(19) United States
(12) Patent Application Publication
(10) Pub. No.: US 2004/0057536 A1
(43) Pub. Date: Mar. 25, 2004

(54) Digital correlator for multiple sequence detection

(75) Inventors: David J. Kasper II, Aliso Viejo, CA (US); Craig A. Evensen, Trabuco Canyon, CA (US)

Correspondence Address: Fogg and Associates, LLC, P.O. Box 581339, Minneapolis, MN, 55458-1339, US

(73) Assignee: ADC DSL Systems, Inc.

(21) Appl. No.: 10/251,194

(22) Filed: Sep. 20, 2002

(51) Int. Cl. H03D 1/00; H04L 27/06

(52) U.S. Cl. 375/343

(57) ABSTRACT

An apparatus and method is described that allows for improved correlation of multiple signatures from an input datastream, reducing the complexity and memory size of the correlation operation by utilization of a multiple sequence indexing correlator. The multiple sequence indexing correlator keeps an index into each signature that indicates how many elements have been matched so that only the remaining portion of each signature must be compared to the input data stream. Because of this, no history of the input datastream is kept and only a small portion of each signature is compared at one time. Additionally, the multiple sequence indexing correlator allows for ease of signature modification or addition, pre-execution of functions, signatures with identical substrings but differing lengths to be detected, wild card signature elements, timeouts to determine signature end, null functions, execution hold off for extended signatures, and keystroke detection.

### TECHNICAL FIELD

The present invention relates generally to devices with embedded processors and in particular the present invention relates to devices that must recognize patterns in datastreams.

### BACKGROUND

In some electronic systems, input signals are analyzed to determine whether the input signal matches one or more known patterns or “signatures”. When the input signal matches one of the patterns, the electronic circuit takes selected action. For example, in a wireless communication system, when an input stream matches a known synchronization pattern, the system begins processing data received over a wireless link. Operations that can require specific pattern recognition, herein referred to as correlation, include, but are not limited to, recognizing control codes in a general datastream, event initiation codes, keystrokes, or communication protocol markers and framing codes. Some typical devices that contain correlators, include, but are not limited to computer systems, communication devices, wireless communication devices, and computer based devices with embedded processors. Correlation is particularly a problem when the patterns to be recognized are intermixed with other data in a datastream or input signal. As stated above, in many of these cases, such as communication devices, the incoming signatures of the datastream are intermixed with other data and must be characterized by the correlator as either data to be passed on to other systems of the electronic circuit, or signature patterns that must be recognized and acted upon, such as keystrokes or control codes. Generally, once such a pattern is correlated in the input signal, an action, event, or function that is associated with the occurrence of the specific pattern is executed by the electronic circuit.

With present correlation methods or apparatuses, a history is kept in memory of the input datatream by the device containing the correlator. Typically this history is assembled by the electronic circuit by buffering the input signal and then sampling the buffer on a periodic basis, placing the sample into memory. Testing is then done for correlation on the individual bits, elements, or characters, referred to herein as elements, of the input signal stored in memory. Generally, the history of the input datastream kept in memory is tested for correlation by subtracting the signature of each pattern to be recognized with the history. When the result is zero, and thus all elements of the signature match the input datastream, the overall signature matches or correlates to the current input datastream. Alternatively, the input history can be logically compared to the signature by XOR-ing, AND-ing, or XNOR-ing the individual elements of the input to each signature element to check for correlation. Commonly, the correlator is implemented in hardware or software of the electronic circuit as a state machine, which matches each individual element of the signatures it must recognize to the input datastream.

Modern correlators in digital devices have many issues that can lead to problems for system designers and maintainers. In particular, the high memory requirements of the input history and the processor requirements of the correlation process can lead to issues for electronic circuits that contain embedded processors, memories, and systems which are typically limited in available resources. Many of these electronic circuits typically utilize a processor and memory system with a size and throughput that is closely matched to the needs of operating the device to reduce the overall cost and power requirements of the system. Therefore, there is generally not an excess of spare resources available to devote to correlation tasks in addition to the normal operating requirements of the device. Also, as more signatures that must be checked for are added to the correlator, the more complex and resource intensive the task of correlation becomes. Because of this, as the number of signatures increases, the correlator implementation becomes more complex and thus processor throughput and system memory requirements increase. Additionally, state machine correlators must be carefully designed and verified to ensure their proper operation. When the signature patterns are then later changed, or if additional signature patterns are added, the state machine must then be partially or fully re-designed and then re-verified. Therefore, changing or adding new signatures in state machine correlators becomes a non-trivial task and likely source for errors for system implementers. In particular, this becomes a problem for keystroke correlators of electronic circuits that accept and recognize a large number of complex keystroke patterns and/or device commands that can be subject to change.

For the reasons stated above, and for other reasons stated below which will become apparent to those skilled in the art upon reading and understanding the present specification, there is a need in the art for a method and apparatus for efficiently detecting multiple specific data patterns in datastreams with electronic circuits and, in particular, communication devices.

### SUMMARY

The above-mentioned problems with detecting multiple patterns in electronic circuits are addressed by embodiments of the present invention and will be understood by reading and studying the following specification.

Embodiments of the present invention correlate an input stream to a set of signatures without requiring storage of the input signal. This is accomplished by comparing the input signal element-by-element as received with the elements of each signature of the set. If a string of the input signal does not match with a given signature of the set of signatures, the process restarts the comparison of the given signature with the next element of the input signal with the beginning of the given signature of the set of signatures. Further, when a string of the input signal does match a given signature of the set of signatures, the process also starts with the beginning of the given signature and the next element of the input signal.

In one embodiment, a method for correlating an input signal to a signature from a set of stored signatures is provided. The method compares an input stream with each signature of the set of signatures element-by-element as the input stream is received. The method restarts the comparison of a given signature for the next element in the input stream with the first element of the given signature when an element in the input stream does not match the compared element in the signature. The method declares correlation when consecutive elements in the input stream match corresponding elements of an entire signature from the set of signatures.

Other embodiments are described and claimed.

### BRIEF DESCRIPTION OF THE DRAWINGS

FIG. 1 is a block diagram of an embodiment of an electronic circuit with digital correlation according to the teachings of the present invention.

FIG. 2 is a simplified flowchart of a multiple sequence indexing correlator algorithm according to one embodiment of the present invention.

FIG. 3 is a simplified flowchart of a multiple sequence keystroke indexing correlator algorithm according to one embodiment of the present invention.

### DETAILED DESCRIPTION

In the following detailed description, reference is made to the accompanying drawings that form a part hereof, and in which is shown by way of illustration specific embodiments in which the inventions may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense, and the scope of the present invention is defined only by the claims.

Indexing correlators are a form of correlator that operate by correlating an input datastream to a signature by maintaining an index that corresponds to an offset into the signature to be matched. As the input datastream is sampled, the individual elements or sets of elements in each input datastream sample are matched by the correlator to the initial portion of the signature and the index into the signature is advanced to point to the next unmatched element. As additional elements are sampled from the input stream and matched to the signature, starting from the element pointed to by the index, the index is further advanced to the next unmatched element. When a mismatch occurs the index into the signature is reset to the first element of the signature. When the final element of the signature is matched and the index is equal to the length of the signature, the signature has been correlated and the action, event, or function that is associated with the signature is executed by the electronic circuit. As a result of the indexing correltor's method of operation, no history of the input stream is kept in memory and only M=log₂N bits are required in memory for the index to represent a signature of N elements in length. Additionally, the processor or hardware used in correlation only compares a small section of the signature to the input sample at any one time. Therefore correlation is accomplished with a minimum of overhead and impact upon resource limited electronic circuit hardware, processors, and memory systems. Furthermore, the index corresponds to a percentage match or measure of how much of the current input datastream corresponds to the signature being matched, allowing measures of confidence in the signature and pre-execution when a signature index progresses beyond a selected confidence level.

An example of such indexing pattern correlation of a signature is described in the U.S. patent application Ser. No. ______ (Attorney Docket No. 100.455US01) titled “Digital Correlation” by David J. Kasper II, which is commonly assigned and is incorporated herein by reference.

Embodiments of the present invention utilize an improved apparatus and/or method to correlate multiple signature patterns in an input datastream by utilizing a multiple sequence indexing correlator. Multiple sequence indexing correlators are indexing correlators that can match multiple signature patterns at once, utilizing the above indexing correlator apparatus and/or methodology. In a multiple sequence indexing correlator multiple signatures are matched/correlated at a single time to an input datastream. The multiple sequence indexing correlator maintains a number of signatures, typically in non-volatile memory such as a Flash memory or ROM, that are checked for in the input datastream. The multiple sequence indexing correlator also maintains an index for each signature in memory, also known as a correlation status. Each index/correlation status corresponds to an offset into its associated signature. As the input datastream is sampled and individual elements or sets of elements in each input datastream sample are tested by the correlator against each signature in turn (testing each signature against the input datastream in an effectively parallel manner) until the input datastream sample has been tested against each signature that is held in memory of the electronic circuit. When an element or set of elements contained the immediate input datastream sample matches a portion of an individual signature, the index (correlation status) into the signature is advanced to point to the next unmatched element of the signature. As additional elements are sampled from the input datastream and tested against the set of signatures that are being correlated and matched to an individual signature the associated index of the signature is advanced further so that the next input datastream sample is tested against the remaining unmatched portion of the individual signature. If a mismatch occurs, the associated correlation status/index into the individual signature that failed to match is reset to point to the first element of the signature, restarting the matching process for that particular signature. When a particular correlation status/index is equal to the length of its signature, that signature has been matched/correlated in the input signal or datastream and the action, event, or function that is associated with the signature is dispatched/executed by the electronic circuit.

As with indexing correlators, multiple sequence indexing correlators are computationally efficient in that the processor, hardware, or correlation engine used in correlation is only comparing the input sample to a small section of each signature at a time. Additionally, no history of the input data stream is kept, only an index/correlation status of each signature is kept in memory minimizing the memory requirements. Therefore, correlation to the multiple signatures of the signature set is accomplished in parallel manner with a minimum of overhead and impact upon the electronic circuit hardware, processors, and memory systems. Furthermore, the index/correlation status of each individual signature corresponds to a measure of how much of the current input datastream corresponds to the signature, allowing measures of confidence in the signature and pre-execution of commands by the electronic circuit when the index/correlation status of a given signature reaches a predetermined correlation level/index value. In this situation the probability that the command or function associated with the signature will be executed is high and certain tasks of the associated actions/functions can be preemptively executed by the electronic circuit to improve responsiveness. Furthermore, signatures are easily updated and additional signatures may be easily added to multiple sequence indexing correlator embodiments of the present invention by modifying the table of signatures and indexes held in memory of the electronic circuit. This allows the multiple sequence indexing correlator of the present invention to be conveniently modified, added to, or repurposed without the rigorous re-design and testing required of state machine correlators.

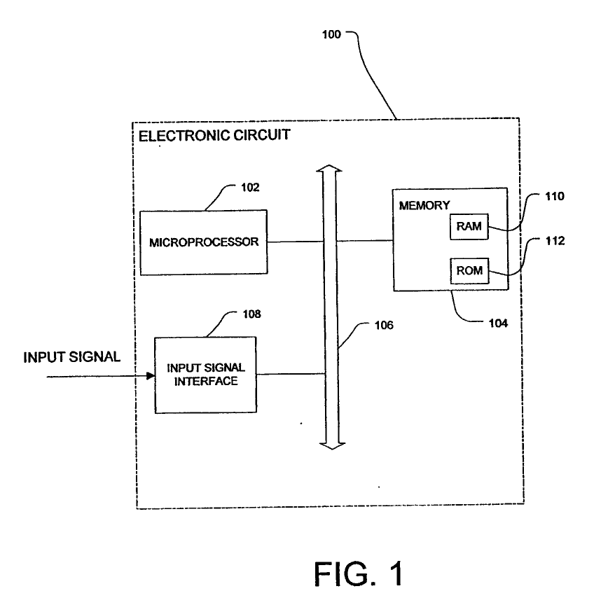

FIG. 1 is a block diagram of an embodiment of an electronic circuit, indicated generally at 100, that correlates and input signal to one or more signatures according to the teachings of the present invention. In one embodiment, the input signal comprises a stream of elements that are received from a source, e.g., over a telecommunications link, from a user input device or other appropriate signal generation mechanism. Advantageously, electronic circuit 100 determines if a sequence of elements of the input signal correlates to all of the elements of each signature in a parallel manner without requiring the storage of a history of the input signal.

Electronic circuit 100 includes microprocessor 102, memory 104 and input signal interface 108. Bus 106 provides an interface between each of microprocessor 102, memory 104 and input signal interface 108. In one embodiment, memory 104 includes random access memory (RAM) 110 and read only memory (ROM) 112. Other embodiments use any appropriate combination of memory types, including, but not limited to RAM (static or dynamic), ROM, electrically erasable programmable read only memory (EEPROM), electrically programmable read only memory (EPROM), flash memory and the like. In one embodiment, microprocessor 102 comprises a dedicated processor for performing the correlation. In other embodiments, microprocessor 102 performs additional functions for the electronic circuit. Further, in other embodiments, microprocessor 102 comprises a special purpose logic or control circuit with a limited set of functionality.

In one embodiment, electronic circuit 100 is incorporated into a computer for identifying one or more selected key combinations for initiating one or more selected actions, e.g., displaying selected data on a screen, initiating a program, etc. In other embodiments, electronic circuit 100 is incorporated in other systems such as telecommunications systems and the like to identify when expected input patterns are received so that appropriate action can be taken.

Software routines that initialize and operate computer based devices, such as the electronic circuit 100 of FIG. 1, are collectively referred to as firmware or ROM after the non-volatile read only memory (ROM) machine usable storage device that such routines have historically been stored in. It is noted that such firmware or ROM routines are stored on a variety of machine usable storage mediums or firmware storage mediums that include, but are not limited to, a non-volatile Flash memory, a read only memory (ROM), an electrically erasable programmable read only memory (EEPROM), a one time programmable (OTP) device, a complex programmable logic device (CPLD), an application specific integrated circuit (ASIC), a magnetic media disk, etc. It is also noted that electronic circuits incorporating multiple sequence indexing correlators can take multiple other physical forms, including, but not limited to, electronic circuits that are functions of other systems, or electronic circuits that have the multiple sequence indexing correlator functionality expressed in firmware or even hard-coded in a device such as an application-specific integrated circuit (ASIC) chip.

In one embodiment, electronic circuit 100 uses a number of parameters to determine correlation between the input signal and each signature. For example, electronic circuit 100 uses an index, a signature and a signature length for each signature to be recognized. In one embodiment, the signatures are determined at compile time and are stored in ROM 112 as arrays of elements, e.g., each signature containing elements K₀, K₁, K₂, . . . , and K_{(N-1)} for an array of N elements each. In other embodiments, the signatures are stored in RAM 110. Further, the length N of each signature is also determined at compile time and stored in ROM 112. In other embodiments, the length N of each signature is stored in RAM 110. Finally, the index/correlation status of each signature is maintained in RAM 110 during operation of the process. Each index indicates the current level of correlation between the input signal and the signature it represents because the index is related to how many of the signature elements have been matched to sequential elements in the input stream. Each index is initialized to zero during power-up initialization.

In operation, electronic circuit 100 identifies correlation between any set of sequential elements in an input signal received at input signal interface 108 with a set of one or more signatures stored in memory 104. Initially, an element of the input signal is received at interface 108. Microprocessor 102 retrieves a next element of each signature from memory 104. Until a match is found with any element of the input stream, microprocessor 102 retrieves the first element of each signature. Once the first element of a particular signature has been matched that signature is partially matched and the microprocessor 102 retrieves the next element of the signature for the next comparison with an element of the input signal. The next element of each partially matched signature is retrieved from memory 104 by the microprocessor 102 for each following comparison of an element of the input signal, so long as each element matches successive elements of the input signal. When the microprocessor 102 determines that any element of the input signal does not match the compared element of a partially matched signature, the microprocessor returns to the first element of the particular signature for the following comparison of an element of the input signal. This allows each signature of the set of signatures in memory 104 to be matched in a parallel manner to an input signal without maintaining any history of the input signal in memory.

In one embodiment, the retrieval and comparison of elements is accomplished using an index/correlation status value that is associated with each signature of the set of signatures. Elements of each signature are retrieved based on the current value of the associated index. Each index begins at zero. On each match between an element of the input stream and a retrieved element of a particular signature, the associated index is incremented. The next element for the particular signature is retrieved from a memory location determined by a base address for the signature and an offset derived from the associated index. When the associated index is equal to the length of a particular signature, that signature has been matched with a sequential portion of the input signal.

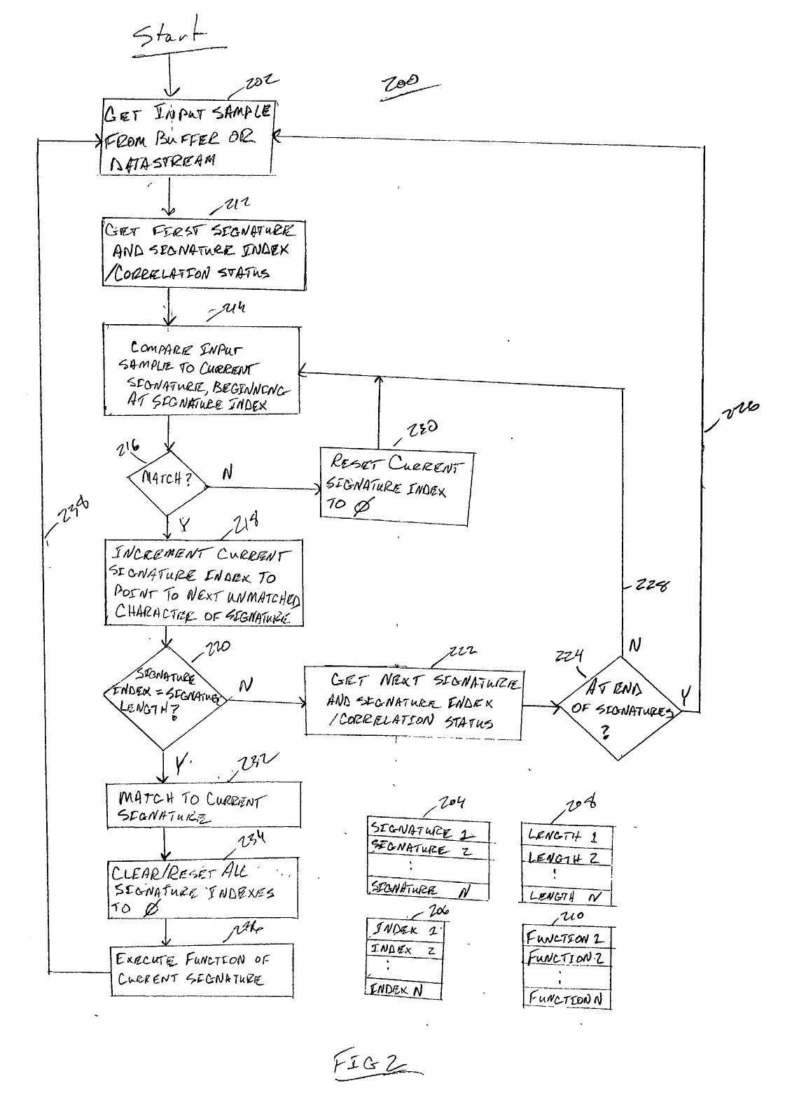

In another embodiment, electronic circuit 100 uses the process of FIG. 2, described below, to determine correlation between an input signal and a set of signatures.

FIG. 2 is a simplified flowchart of a multiple sequence indexing correlator algorithm 200 of an electronic circuit 100 according to an embodiment of the present invention. In the multiple sequence indexing correlator algorithm 200 of FIG. 2, an input sample is retrieved 202 from the input signal datastream or from a buffer at the input signal interface of the electronic circuit 100. The correlator then retrieves 212 the first signature and the first signature index/correlation status for use as the current signature and current index from a signature table 204 and an index table 206 in the memory 104. It is noted that the signature table and index table can have other possible implementations, including, but not limited to a table of pointers to distributed memory locations, an array, and hardcoded values compiled into the executable (i.e., for the non-variable signatures). The input sample is then compared 214 to the current signature with current index offset. The compare operation is by standard comparison techniques, including, but not limited to subtraction, XNOR, or AND. When there is a match 216, the current signature index is incremented 218 to next unmatched character of the current signature. The current signature index is then compared 220 to the length of the current signature from the signature length table 208 stored in memory 104. In another embodiment, the multiple sequence indexing correlator algorithm 200 generates the signature length of the current signature from the signature table 204 in memory 104 to compare to the current index. If the current index and the current signature length do not equal, the multiple sequence indexing correlator algorithm 200 gets the next signature and associated signature index/correlation status 222 from the signature 204 and index 206 tables in memory 104. If the multiple sequence indexing correlator algorithm 200 is at the end of the signatures 224 in signature table 204, the multiple sequence indexing correlator algorithm 200 returns 226 to get the next input sample from the input buffer or input datastream 202. If the multiple sequence indexing correlator algorithm 200 is not at end of signatures 224 in the signature table 204, the algorithm returns 228 to compare 214 the current signature to the input sample beginning at the current index offset. It is noted that there are multiple manners to determining the end of the signature table 204, including, but not limited to determining the length of the table at compile time, ending the table with a special marking signature, or ending the table with a NULL signature.

When a mismatch 216 occurs in the comparison of the elements of the input sample to the elements of the current signature at the current index offset, the index of the current signature is reset 230 to zero and the multiple sequence indexing correlator algorithm 200 then returns to once again compare 214 the current input sample to the current signature and reset index. Because of the reset index, however, the following comparison with the current signature and the input sample will begin again with the first element of the current signature.

When the signature index is equal to the signature length 220, the input datastream has been completely matched 232 to the current signature. The algorithm 200 of FIG. 2 then resets/clears 234 all the signature indexes of the index table 206 to zero and initiates execution 236 of the function associated with the matched signature in the function table 210. This clearing of the indexes 234 in the index table 206 allows the multiple sequence indexing correlator algorithm 200 to guarantee that it is starting from a known state once the algorithm 200 begins comparing the input sample to the signatures again. Upon dispatch of execution of the associated function 236, the multiple sequence indexing correlator algorithm 200 returns 238 to restart correlation of the input signal/datastream to the signatures of the signature table 204 and gets/retrieves 202 the next input sample from the input datastream or input buffer.

It is noted that in one embodiment the multiple sequence indexing correlator algorithm 200 does not clear the indexes of the index table 206 upon matching a signature in the input signal/datastream. In operation, the algorithm 200 will automatically clear individual indexes/correlation statuses of the index table 206 as particular signatures fail matching 216 the input signal/datastream and the associated indexes are reset to zero 230. This automatic clearing of the indexes of the index table 206 is particularly thorough when the signatures are “orthogonal” and do contain strings or substrings of elements that are common to two or more of the signatures. Thus, in a multiple sequence indexing correlator algorithm 200 utilizing an orthogonal signature set, when there is a match to a signature there are no partial matches in the index table 206 due to the fact that there are no substrings or strings that are common to two or more of the signatures in the signature set.

The partial match characteristic in multiple sequence indexing correlator algorithms 200 due to common strings or substrings can also be utilized to allow for extended signature matching in one embodiment of the present invention. In extended signature matching, a matched signature can be a sub-string of a longer signature. For example, the “ESC” character versus an escape control sequence which begins with “ESC [”. The longer signature is then differentiated from the shorter signature and recognized by the next element to be received/sampled by the electronic circuit. To aid in recognition of extended signatures, another embodiment of the present invention utilizes a special timeout element/character to detect the gap in input after the shorter signature. The timeout element is added to the shorter signature of any given pair of signatures with common strings of elements to allow the shorter signature to be easily differentiated from the longer signature. The timeout character is then added to the input signal/datastream by the input signal interface 108 of an electronic circuit 100 when an idle period of a predetermined length occurs and no additional input signal element is received. Only upon matching the timeout element in the input data sample does the shorter signature with the common substring become fully matched and the associated function executed. For example, the signature for the isolated escape character, “ESC” then becomes “ESC Timeout” to allow it to be differentiated from an escape sequence beginning with “ESC [”.

In one embodiment of the present invention, the multiple sequence indexing correlator algorithm 200 utilizes a special “wildcard” character/element in its set of signatures that will match any received input element for an element position of a given signature that it is positioned into. This allows a given signature to have fixed and variable elements and allows for multiple matches for a single signature. This increases correlation algorithm and processor efficiency by only having to match a single signature for multiple simple variances. With wildcard elements, the system designer can blank elements from the input sequence, or pass through of data to functions. Execution of a matched signature's associated function can also be “held off” on a signature if one or more wild card elements are appended to the signature as the last element(s), so that the signature is effectively fully matched, but execution of the associated function is delayed until the next character(s)/element(s) come in and fills the remaining wildcard element(s). Wildcard elements also allow system designers to discard unused information in a signature, such as header information, which are part of a signature but are not necessary to uniquely identify it or are common to a series of similar signatures.

In one embodiment of the present invention, the multiple sequence indexing correlator algorithm 200 utilizes a specialized function, called a NULL function, that when the associated signature pattern is matched, does nothing. Utilizing a NULL function the system designer can “reject” certain input from the electronic circuit. This allows for the multiple sequence indexing correlator algorithm 200 to drop certain input from the electronic circuit as neither a signature to be acted upon or data to be passed to another system of the electronic circuit.

In one embodiment of the present invention, the multiple sequence indexing correlator algorithm 200 utilizes a global correlation status that is an OR function of all the individual correlation statuses/indexes of the algorithm. Such a global correlation status allows the algorithm to tell the electronic circuit if the input is data (OR function is 0) or is partially/fully correlated to some signature (OR function is non-zero) without requiring a full match of the signature to be effected. This can allow the electronic circuit to directly pass the non-signature data information to other systems of the electronic circuit with a minimum of delay. In another embodiment of a multiple sequence indexing correlator algorithm 200 the addition of simple logic allows the global correlation status to report the signature that is matched when it is fully correlated to a signature, in addition to reporting whether the input signal is non-signature (i.e., data) or is a partial match to one or more signatures. For example, if the global correlation status is hexadecimal “FF” there is no match to a signature and the input is data, if the global correlation status is “FE” it is partially matched to a signature. When the input signal is fully matched to some signature, the global correlation status then indicates which signature is matched by reporting an index in the range of “FD” to “00”

In one embodiment of the present invention, the multiple sequence indexing correlator algorithm 200 utilizes a set of signatures that are prioritized by ordering in the set of signatures, with the set of signatures ordered by the likelihood of occurrence in the input datastream. This allows for improvement in the overall efficiency of the multiple sequence indexing correlator algorithm 200 for once a signature is matched there is no need to continue comparing the input sample to the rest of the signatures remaining in the signature table. It is noted that this can also be utilized to gain speed of correlation/execution for any selected signature and associated function by the system designer placing them closer to the beginning of the table of signatures. For example, in one embodiment of the present invention the signatures of an electronic circuit are listed with the common device configuration commands occurring first in the signature table, whereas manufacturer specific configuration commands that are mainly used for configuration of the device at the factory, and thus seldom used, are listed last. It is noted that this ordering is independent of signature size. It is also noted that this prioritization increases in overall efficiency as the number of elements contained in each input sample increases.

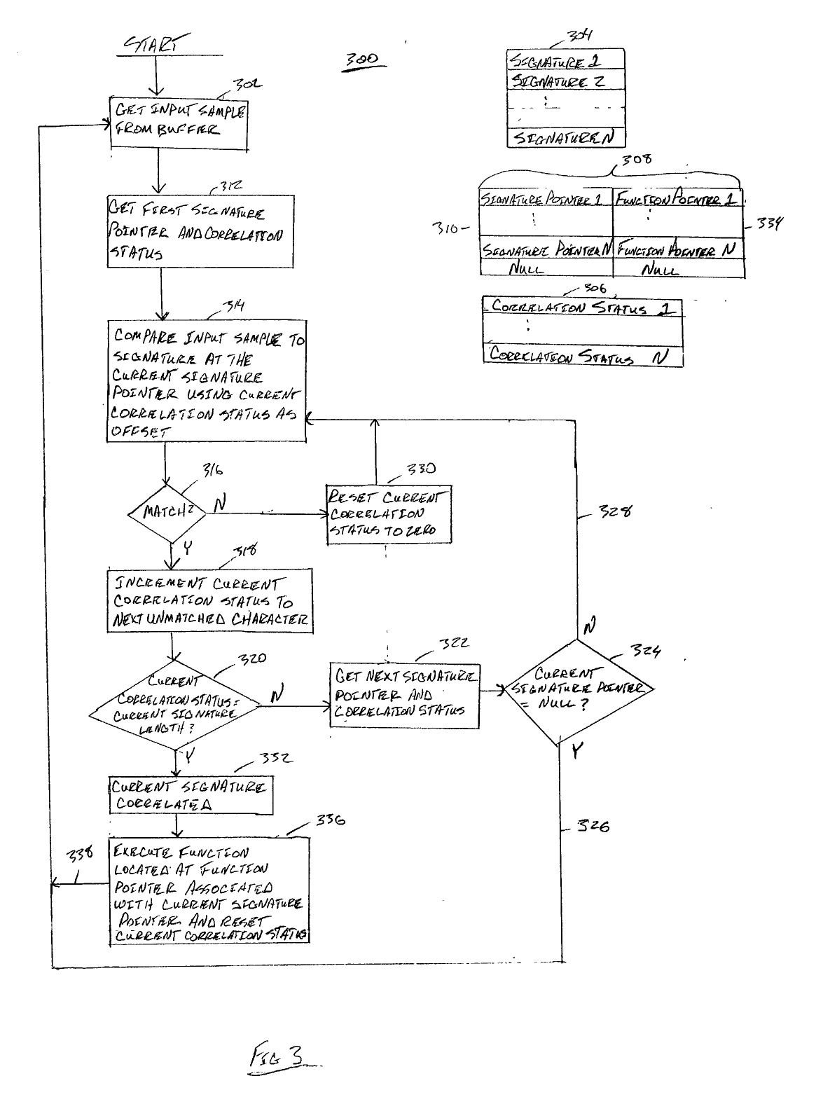

FIG. 3 is a simplified flowchart of a multiple sequence indexing correlator algorithm 300 according to another embodiment of the present invention. In the multiple sequence indexing correlator algorithm 300 of FIG. 3, an input sample is retrieved 302 from a buffer of the input signal datastream at the input signal interface of the electronic circuit 100. The correlator then retrieves 312 a first signature pointer and a first signature index/correlation status from a correlation status table 306 and a table 308 of signature pointers 310 and associated function pointers 334 in the memory 104 for use as the current signature and the current correlation status/index. The elements of the input sample are then compared 314 to the elements of the signature stored at the current signature pointer using the current correlation status as an offset into the signature. When there is a match 316, the current correlation status/signature index is incremented 318 to next unmatched element of the current signature. The current correlation status is then compared 320 to the length of the signature stored at the current signature pointer. If the current correlation status is not greater than or equal to the signature length, the algorithm 300 gets the next signature pointer and associated correlation status/signature index 322 from the correlation status table 306 and the table 308 of signature pointers 310 and associated function pointers 334. When the algorithm 300 retrieves a NULL from the table of signature pointers 310, it is at the end of the signatures 324 to be correlated. The multiple sequence indexing correlator algorithm 300 then returns 326 to get the next input sample from the input buffer 302 and restarts comparing again from the first signature. When the multiple sequence indexing correlator algorithm 300 does not retrieve a NULL signature pointer from the table of signature pointers 310, it is not at end of signatures 324 to be correlated. The multiple sequence indexing correlator algorithm 300 will then return 328 to compare 314 the next signature which is now at the current signature pointer to the input sample beginning at the offset indicated by the current correlation status.

When a mismatch 316 occurs in the comparison of the input sample to the signature at the current signature pointer at the current correlation status offset, the current correlation status is reset 330 to zero. The multiple sequence indexing correlator algorithm 300 then returns to once again compare 314 the current input sample to the current signature and reset index. Because of the current correlation status being reset, the comparison of the signature at the current signature pointer and an input sample will begin again with the first element or character of the signature. The multiple sequence indexing correlator algorithm 300 then, as described above, proceeds to get 322 the next signature pointer and associated correlation status and checks 324 to see if it is at the end of the signatures 324 to be correlated by checking if the retrieved signature pointer is a NULL. It will return 326 to get the next input sample 302 if the current signature pointer is a NULL, or return 328 to compare 314 the current input sample to the next signature and correlation status if the signature pointer is not a NULL.

When the signature index is greater than or equal to the signature length 320, the input datastream has been completely matched 332 to the current signature. The multiple sequence indexing correlator algorithm 300 of FIG. 3 then resets the current correlation status and initiates execution 336 of the function at the function pointer 334 associated with the signature pointer 310 of the matched signature in table 308. The multiple sequence indexing correlator algorithm 300 of FIG. 3 does not reset the correlation statuses/signature indexes of the correlation status table 306 to zero. Upon execution of the associated function 336, the multiple sequence indexing correlator algorithm 300 returns 338 to begin the correlation of the input signal/datastream to the signatures of the signature table 304 again and gets/retrieves 302 the next input sample from the input buffer.

Alternative computer based system and device embodiments of the present invention with a multiple sequence indexing correlator circuit and/or method will be apparent to those skilled in the art with the benefit of the present disclosure, and are also within the scope of the present invention.

### CONCLUSION

An apparatus and method has been described that allows for improved correlation of multiple signatures from an input datastream, reducing the computational complexity and memory size of the correlation operation in electronic circuits by utilization of a multiple sequence indexing correlator allowing for a reduction of the overhead of on the limited resources of the electronic circuit. The multiple sequence indexing correlator keeps an index into each signature that indicates how many elements of the signature have been matched so that the remaining portion of each signature only needs to be compared to the most recently sampled elements of the input data stream, allowing the correlator to avoid keeping a history of the input datastream and having to compare full signatures. Multiple sequence indexing correlators also allow for improved modification and addition of signatures to be detected without the difficulty of redesign and verification associated with state machine correlators. The improved device apparatus and method also allows for pre-execution functions associated with individual signatures when the signature's index reaches a predetermined match level or confidence. The improved device apparatus and method additionally allows for signatures with identical substrings but differing lengths to be detected, wild card signature elements, timeouts to determine signature end, null functions, execution hold off to allow for extended signatures, and keystroke detection.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A method for correlating an input signal to a plurality of signatures, the method comprising:
receiving an element of the input signal;
comparing the element of the input signal to an element of each signature of the plurality of signatures;
when the element of the input signal matches the element of an individual signature of the plurality of signatures, comparing a next element of the input signal to a next element of the individual signature;
when the element of the input signal does not match the element of the individual signature of the plurality of signatures, comparing the element of the input signal to the first element of the individual signature; and
declaring correlation when the input signal sequentially matches all of the elements of the individual signature of the plurality of signatures.

2. The method of claim 1, further comprising:
executing a function associated with the individual signature when the signature is declared correlated.

3. The method of claim 2, wherein executing a function associated with the individual signature when the signature is declared correlated further comprises executing a NULL function when the signature is declared correlated.

4. The method of claim 1, further comprising:
storing correlation routines on a machine readable storage medium.

5. The method of claim 1, further comprising:
determining the next element of each signature based on an associated index.

6. The method of claim 5, further comprising:
incrementing the associated index when the element of the input signal matches the element of the signature.

7. The method of claim 5, further comprising:
determining when the input signal sequentially matches all of elements of a individual signature of the plurality of signatures based on comparing the associated index of the individual signature with the size of the individual signature.

8. The method of claim 5, further comprising:
pre-executing an associated function upon partial correlation of the individual signature when a selected index value of the associated index occurs.

9. The method of claim 5, further comprising:
clearing the associated index of each signature of the plurality of signatures when correlation is declared.

10. The method of claim 5, further comprising:
retaining the contents of the associated index of each signature of the plurality of signatures when correlation is declared.

11. The method of claim 5, further comprising:
determining the overall correlation status of the plurality of signatures with a global correlation status.

12. The method of claim 11, wherein the global correlation status is an OR function of the associated index of each signature of the plurality of signatures.

13. The method of claim 1, wherein the plurality of signatures are orthogonal to each other.

14. The method of claim 1, wherein two or more signatures of the plurality of signatures contain a common string of elements.

15. The method of claim 1, wherein a first signature of the plurality of signatures is substring of one or more second signatures.

16. The method of claim 15, further comprising:
differentiating between the first signature and the one or more second signatures by appending a timeout element to the first signature and matching the timeout element to an inserted timeout element, wherein an input interface inserts the timeout element to the input signal when the input interface is idle for a selected time period.

17. The method of claim 1, wherein one or more signatures of the plurality of signatures contain wildcard elements.

18. The method of claim 1, further comprising:
prioritizing the plurality of signatures to be compared in order of likelihood of occurrence.

19. A method for correlating an input signal to a plurality of signatures, the method comprising:
initializing an associated index value for each signature of the plurality of signatures;
sampling an input signal;
comparing the current sample of the input signal to one or more elements of each signature, wherein each comparison begins with the one or more elements of each signature stored at a location offset by the index value associated with each signature from a signature base address of the signature;
when a match is not detected with a given signature of the plurality of signatures, resetting the associated index value of the signature;
when a match is detected with a given signature of the plurality of signatures, incrementing the associated index of the signature;
comparing the associated index of each signature to a selected length associated with each signature;
when the associated index does not match the selected length for a given signature of the set of signatures, returning to sampling the input signal; and
when the associated index does match the associated selected length for a given signature of the set of signatures, declaring correlation.

20. The method of claim 19, further comprising:
executing a function associated with the given signature when the signature is declared correlated.

21. The method of claim 19, further comprising:
clearing the associated index of each signature of the plurality of signatures when correlation is declared.

22. The method of claim 19, further comprising:
determining the overall correlation status of the plurality of signatures with a global correlation status.

23. The method of claim 19, wherein the plurality of signatures are orthogonal to each other.

24. The method of claim 19, further comprising:
differentiating between a first signature of the plurality of signatures and one or more second signatures of the plurality of signatures by appending a timeout element to the first signature, wherein an input interface inserts a timeout element into the input signal when the input interface is idle for a selected time period.

25. The method of claim 19, wherein one or more signatures of the plurality of signatures contain wildcard elements.

26. The method of claim 19, further comprising:
prioritizing the plurality of signatures to be compared in order of likelihood of occurrence.

27. The method of claim 19, wherein comparing the associated index of each signature to a selected length associated with each signature further comprises comparing the associated index of a given signature to a selected length associated with the given signature directly after the current sample of the input signal is compared against the given signature.

28. The method of claim 19, wherein comparing the associated index of each signature to a selected length associated with each signature further comprises comparing the associated index of each signature to a selected length associated with each signature after all signatures of the plurality of signatures have been compared against the current sample of the input signal.

29. A method of operating an electronic circuit, comprising:
retrieving a sequence of input samples having one or more elements each from an input signal at an input interface;
comparing each input sample to each signature of a plurality of signatures, wherein the one or more elements of an individual input sample are compared to one or more elements of each signature of the plurality of signatures starting from an offset into each signature that is selected by an associated correlation status of the signature;
incrementing the associated correlation status of an individual signature of the plurality of signatures to the next unmatched element of the individual signature when a match occurs between the one or more elements of the input sample and the one or more elements of the individual signature, starting from the offset into the signature selected by the associated correlation status;
resetting the associated correlation status of an individual signature of the plurality of signatures when a mismatch occurs between the one or more elements of the input sample and the one or more elements of the individual signature, starting from the offset into the signature selected by the associated correlation status; and
declaring the input signal and an individual signature of the plurality of signatures to correlate when the associated correlation status of the individual signature is equal to the length of the signature.

30. The method of claim 29, further comprising:
executing a function associated with the individual signature when the input signal is declared to correlate with the individual signature.

31. The method of claim 29, further comprising:
clearing the associated correlation status of each signature of the plurality of signatures when correlation is declared.

32. The method of claim 29, further comprising:
retaining the contents of the associated correlation status of each signature of the plurality of signatures when correlation is declared.

33. The method of claim 29, further comprising:
determining the overall correlation status of the plurality of signatures with a global correlation status.

34. The method of claim 29, wherein the plurality of signatures are orthogonal to each other.

35. The method of claim 29, further comprising:
differentiating between a first signature of the plurality of signatures and one or more second signatures of the plurality of signatures by appending a timeout element to the first signature, wherein the input interface inserts a timeout element into the sequence of input samples when the input signal is idle for a selected time period.

36. The method of claim 29, wherein one or more signatures of the plurality of signatures contain wildcard elements.

37. The method of claim 29, further comprising:
prioritizing the plurality of signatures to be compared in order of likelihood of occurrence.

38. An electronic circuit, comprising:
a processor;
a memory for storing a set of signatures;
an input signal interface, adapted to receive an input signal;
a bus, communicatively coupled to the processor, the memory and the input signal interface; and
wherein the processor is adapted to compare elements of the input signal with elements of each signature of a set of signatures, element-by-element as the elements are received to determine correlation between the input signal and each signature of the set of signatures without storing the input signal.

39. The electronic circuit of claim 38, wherein the memory further stores an associated index for each signature of the set of signatures.

40. The electronic circuit of claim 38, wherein the memory further stores an associated size for each signature of the set of signatures.

41. The electronic circuit of claim 38, wherein the processor compares an element of the input stream with the first element of a given signature of the set of signatures following a mismatch between the element of the given signature and an element of the input signal.

42. A multiple sequence indexing correlator, comprising:
a processor;
a memory coupled to the processor, wherein the memory contains a plurality of signatures and a plurality of indexes, where each index is associated with a signature of the plurality of signatures;
an input interface coupled to the processor and the memory, wherein the input interface is adapted to receive an input signal in a sequence of input samples having one or more elements each; and
wherein the processor is adapted to compare elements of the input signal with elements of each signature of the plurality of signatures by:
comparing each input sample to each signature of a plurality of signatures, wherein the one or more elements of an individual input sample are compared to one or more elements of each signature of the plurality of signatures starting from an offset into each signature that is selected by an associated index of the signature;
incrementing the associated index of an individual signature of the plurality of signatures to the next unmatched element of the individual signature when a match occurs between the one or more elements of the input sample and the one or more elements of the individual signature, starting from the offset into the signature selected by the associated index;
clearing the associated index of an individual signature of the plurality of signatures when a mismatch occurs between the one or more elements of the input sample and the one or more elements of the individual signature, starting from the offset into the signature selected by the associated index; and
declaring the input signal and an individual signature of the plurality of signatures to correlate when the associated index of the individual signature is equal to the length of the signature.

43. The multiple sequence indexing correlator of claim 42, wherein the processor is further adapted to compare elements of the input signal with elements of each signature of the plurality of signatures by:
executing a function associated with the individual signature when the input signal is declared to correlate with the individual signature.

44. The multiple sequence indexing correlator of claim 42, wherein a first signature of the plurality of signatures is substring of one or more second signatures.

45. The multiple sequence indexing correlator of claim 44, wherein the processor is further adapted to compare elements of the input signal with elements of each signature of the plurality of signatures by:
differentiating between the first signature and the one or more second signatures by appending a timeout element to the first signature, wherein the input interface inserts a timeout element into the sequence of input samples when the input signal is idle for a selected time period.

46. The multiple sequence indexing correlator of claim 42, wherein one or more signatures of the plurality of signatures contain wildcard elements.

47. The multiple sequence indexing correlator of claim 42, wherein the processor is further adapted to compare elements of the input signal with elements of each signature of the plurality of signatures by:
prioritizing the plurality of signatures to be compared in order of likelihood of occurrence.

48. A multiple sequence indexing correlator, comprising:
a correlation engine;
a memory coupled to the correlation engine;
an input interface coupled to the correlation engine and the memory, wherein the input interface is adapted to receive an input signal; and
wherein the correlation engine is adapted to compare elements of the input signal with elements of each signature of a plurality of signatures, element-by-element as the elements are received to determine correlation between the input signal and each signature of the plurality of signatures without storing the input signal.

49. The multiple sequence indexing correlator of claim 48, wherein the memory further stores an associated index for each signature of the set of signatures.

50. The multiple sequence indexing correlator of claim 48, wherein the processor compares an element of the input stream with the first element of a given signature of the set of signatures following a mismatch between the element of the given signature and an element of the input signal.

51. A machine-usable medium having machine-readable instructions stored thereon for execution by a processor of an electronic circuit to perform a method comprising:
retrieving a sequence of input samples having one or more elements each from an input signal at an input interface;
comparing each input sample to each signature of a plurality of signatures, wherein the one or more elements of an individual input sample are compared to one or more elements of each signature of the plurality of signatures starting from an offset into each signature that is selected by an associated correlation status of the signature;
incrementing the associated correlation status of an individual signature of the plurality of signatures to the next unmatched element of the individual signature when a match occurs between the one or more elements of the input sample and the one or more elements of the individual signature, starting from the offset into the signature selected by the associated correlation status;
resetting the associated correlation status of an individual signature of the plurality of signatures when a mismatch occurs between the one or more elements of the input sample and the one or more elements of the individual signature, starting from the offset into the signature selected by the associated correlation status; and
declaring the input signal and an individual signature of the plurality of signatures to correlate when the associated correlation status of the individual signature is equal to the length of the signature.

52. The machine-usable medium of claim 51, further comprising:
executing a function associated with the individual signature when the input signal is declared to correlate with the individual signature.

53. The machine-usable medium of claim 51, further comprising:
determining the overall correlation status of the plurality of signatures with a global correlation status, wherein the global correlation status is an OR function of the associated correlation status of each signature of the plurality of signatures.

54. The machine-usable medium of claim 51, wherein a first signature of the plurality of signatures is substring of one or more second signatures.

55. The machine-usable medium of claim 54, further comprising:
differentiating between the first signature and the one or more second signatures by appending a timeout element to the first signature, wherein the input interface inserts a timeout element into the sequence of input samples when the input signal is idle for a selected time period.

56. The machine-usable medium of claim 51, wherein one or more signatures of the plurality of signatures contain wildcard elements.

57. The machine-usable medium of claim 51, further comprising:
prioritizing the plurality of signatures to be compared in order of likelihood of occurrence.
